(19) United States
(12) Patent Application Publication
(10) Pub. No.: US 2011/0292959 A1
(43) Pub. Date: Dec. 1, 2011

(54) SEMICONDUCTOR LASER DEVICE AND METHOD FOR FABRICATING THE SAME

(76) Inventors: Toshitaka Shimamoto, Osaka (JP); Naoto Shimada, Hyogo (JP); Kouji Makita, Hyogo (JP); Yoshiaki Hasegawa, Okayama (JP)

(21) Appl. No.: 13/030,627

(22) Filed: Feb. 18, 2011

(30) Foreign Application Priority Data
May 27, 2010 (JP) 2010-121202

(51) Int. Cl. H01S 5/22; H01L 21/78

(52) U.S. Cl. 372/46.012; 438/33; 257/E21.599

(57) ABSTRACT

A semiconductor laser device includes a semiconductor laminated film including a ridge stripe portion. The semiconductor laminated film includes a first scribed level-different portion formed in a resonator surface which is an edge surface thereof intersecting the ridge stripe portion and a second scribed level-different portion formed in each side surface thereof extending in parallel to the ridge stripe portion, the first scribed level-difference portion is located between the second scribed level-different portion and the ridge stripe portion, a cross-sectional shape of the first scribe level-different portion taken along the resonator surface is polygonal, and one of angles of inclined parts which is located closer to an associated one of the ridge stripe portions is smaller than the other one of the angles located closer to an associated one of the second scribed portions, the inclined parts being sides of the polygonal shape.

### CROSS-REFERENCE TO RELATED APPLICATION

This application claims priority to Japanese Patent Application No. 2010-121202 filed on May 27, 2010, the disclosure of which including the specification, the drawings, and the claims is hereby incorporated by reference in its entirety.

### BACKGROUND

The present disclosure relates to a semiconductor laser device and a method for fabricating the same, and more particularly, relates to a semiconductor laser device including a ridge stripe portion and a method for fabricating the same.

Currently, in general, in a method for fabricating a semiconductor laser device made of nitride semiconductor which has a hexagonal crystal structure, a laminated film including a lower cladding layer, an active layer, and an upper cladding layer is formed on a gallium nitride (GaN) substrate having a main surface with a (0001) plane orientation by epitaxial growth. As an optical waveguide, a ridge stripe portion extending in a <1-100> crystal axis orientation is formed on the upper cladding layer, and a first scribed groove portion extending in a direction perpendicular to the ridge stripe portion and a second scribed groove portion extending in a direction parallel to the ridge stripe portion are formed in the laminated film. Furthermore, after a top-surface electrode is formed on the laminated film to inject a current into the active layer, and a back-surface electrode is formed at an opposite side of the GaN substrate to the side thereof at which the laminated film is formed, a (1-100) plane of the laminated film is exposed by cleavage whose starting point is at the first scribed groove portion, so that the plane serves as a resonator surface.

A surface intersecting the resonator surface is exposed by cleavage using the second scribed groove portion and is divided into quadrangular chips, and then, each of the divided chips is processed to complete the semiconductor laser device.

However, in the nitride semiconductor laser device, irregularities are formed on a divided surface, and thus, the divided surface is easily broken along a direction at 30 degrees to the resonator surface (e.g., in a direction with which a (10-10) plane is exposed). In particular, the generation of cracks and chips at edge parts of a divided chip is a big problem. Also, since the (1-100) plane serving as a resonator surface makes an larger angle with an adjacent plane (e.g., the (10-10) plane) than an angle with a plane intersecting the resonator surface at right angles, as opposed to a gallium arsenide (GaAs) whose crystal structure is a sphalerite structure, cleavage is not easily caused to occur. Moreover, because structures such as the ridge stripe portion and the scribed groove portions, etc., are formed, irregularities such as cracks, etc., are generated in the resonator surface. Therefore, a suitable cleavage method has to be developed.

In recent years, the development of laser scribe technology, even in a surface of rigid nitride semiconductor, has enabled the width and depth of a scribed groove portion and the shapes of an edge part and a cross-section of the scribed groove portion, etc., to be more easily controlled. Cleavage methods which allow the formation of groove portions for guiding in dividing a wafer into chips so that each of the groove portions has a predetermined shape and the reduction of the generation of irregularities such as cracks, etc., have been described, for example, in Japanese Patent Publication No. 2009-117494, etc.

### SUMMARY

However, along with the current trend toward reducing the cost of devices, there are increasing demands for reduction in chip width, and at the same time, it is necessary to reduce the reduction in quality of resonator surfaces due to cracks, etc. Thus, a method which allows processing of chips with a small width in a stable manner is required.

In view of the foregoing problems, it is an object of the present disclose to improve the quality of side surfaces and a resonator surface of a cleaved and divided semiconductor laser device.

To achieve the foregoing object, the present disclosure provides a semiconductor laser device having a configuration including a semiconductor laminated film in which a scribed groove portion having a polygonal cross-sectional shape is formed.

Specifically, a semiconductor laser device according to the present disclosure includes a semiconductor laminated film including a lower cladding layer, an active layer, and an upper cladding layer having a ridge stripe portion which are stacked in this order on a semiconductor substrate, the semiconductor laminated film includes a first scribed level-different portion formed in a resonator surface which is an edge surface of the semiconductor laminated film intersecting the ridge stripe portion and a second scribed level-different portion formed in each side surface of the semiconductor laminated film extending in parallel to the ridge stripe portion, the first scribed level-difference portion is located between the second scribed level-different portion and the ridge stripe portion, a cross-sectional shape of the first scribe level-different portion taken along the resonator surface is polygonal, and one of angles of inclined parts which is located closer to the ridge stripe portion is smaller than the other one of the angles located closer to the second scribed portion, the inclined parts being sides of the polygonal shape which are in contact respectively with both ends of an upper side of the polygonal shape.

In the semiconductor laser device according to the present disclosure, the first scribed level-different portion has a cross-sectional shape with which cracks are directed toward a back-surface side of the semiconductor substrate. Thus, the generation of cracks at the resonance surface can be prevented or reduced. As a result, the quality of the side surfaces and resonance surface of the semiconductor laser device can be improved, thus resulting in an increased yield of chips having a desired shape.

A method for fabricating a semiconductor laser device according to the present disclosure includes the steps of (a) forming a semiconductor laminated film including a lower cladding layer, an active layer, and an upper cladding layer stacked in this order on a semiconductor substrate, (b) forming ridge stripe portions in an upper part of the semiconductor laminated film, (c) forming a plurality of first scribed groove portions in the semiconductor laminated film so that the first scribed groove portions are arranged to be spaced from one another in a direction perpendicular to the ridge stripe portions, (d) forming second scribed groove portions in the semiconductor laminated film so that the second scribed groove portions extend in a direction parallel to the ridge stripe portions, (e) cleaving the semiconductor substrate and the semiconductor laminated film using the first scribed groove portions so that the semiconductor substrate and the semiconductor laminated film are divided into bars, and (f) dividing the bars obtained by cleaving the semiconductor substrate and the semiconductor laminated film into chips using the second scribed groove portions, the first scribed groove portions are arranged to be spaced from one another in a region between each of the ridge stripe portions and an associated one of the second scribed groove portions, a cross-sectional shape of each of the scribed groove portions taken along a direction perpendicular to the ridge stripe portions is polygonal, one of angles of inclined parts which is located closer to an associated one of the ridge stripe portions is smaller than the other one of the angles located closer to an associated one of the second scribed portions, the inclined parts being sides of the polygonal shape which are in contact respectively with both ends of an upper side of the polygonal shape, and in the step (e), each of the first scribed groove portions is pressed so that pressing force is applied in a direction from a part of the first scribed groove portions located closer to the associated one of the second scribed groove portions to a part of the first scribed groove portion located closer to the associated one of the ridge stripe portions, thereby cleaving the semiconductor substrate and the semiconductor laminated film.

According to the method for fabricating a semiconductor laser device according to the present disclosure, each of the first scribed groove portions has a cross-sectional shape with which cracks generated during the cleaving are directed to a back-surface side of the semiconductor substrate. Thus, the generation of cracks at the resonance surface can be prevented or reduced. As a result, the quality of the side surfaces and resonance surface of a divided semiconductor laser device can be improved, thus resulting in an increased yield of chips having a desired shape.

In the method for fabricating a semiconductor laser device according to the present disclosure, it is preferable that the semiconductor substrate is made of nitride semiconductor whose main surface has a (0001) plane orientation, and in the step (e), the semiconductor substrate and the semiconductor laminated film are cleaved along a (1-100) orientation plane.

In the method for fabricating a semiconductor laser device according to the present disclosure, it is preferable that each of the second scribed groove portions is a groove portion continuously extending in parallel to the ridge stripe portion.

In the method for fabricating a semiconductor laser device according to the present disclosure, it is preferable that in the steps (c) and (d), at least one of the first scribed groove portions or the second scribed groove portions are formed by laser irradiation.

As described above, the semiconductor laser device and the method for fabricating the semiconductor laser device according to the present disclosure may allow improvement of the quality of the side surfaces and resonance surface of a divided semiconductor laser device, thus resulting in an increased yield of chips having a desired shape.

### BRIEF DESCRIPTION OF THE DRAWINGS

FIGS. 1A and 1B are views of a semiconductor laser device according to an example embodiment. FIG. 1A is a plan view, and FIG. 1B is a cross-sectional view.

FIG. 2 is a plan view illustrating a configuration of the semiconductor laser device of the example embodiment before a wafer is cleaved and divided into chips.

FIGS. 3A-3C are schematic views illustrating respective steps for fabricating the semiconductor laser device of the example embodiment.

FIGS. 4A-4C are cross-sectional views illustrating respective steps for fabricating the semiconductor laser device of the example embodiment taken along the line IV-IV of FIG. 3C, where the wafer is rotated by 180 degrees with the line IV-IV as an axis.

FIG. 5 is a view of a first scribed groove portion of the semiconductor laser device of the example embodiment including a plan view and a cross-sectional view thereof.

FIGS. 6A and 6B are cross-sectional views illustrating a cross-sectional shape of the first scribed groove portion of the semiconductor laser device of the example embodiment.

FIG. 7 is a graph showing the relationship between θ3 of FIG. 5 and the generation rate of cracks in a resonator surface.

### DETAILED DESCRIPTION

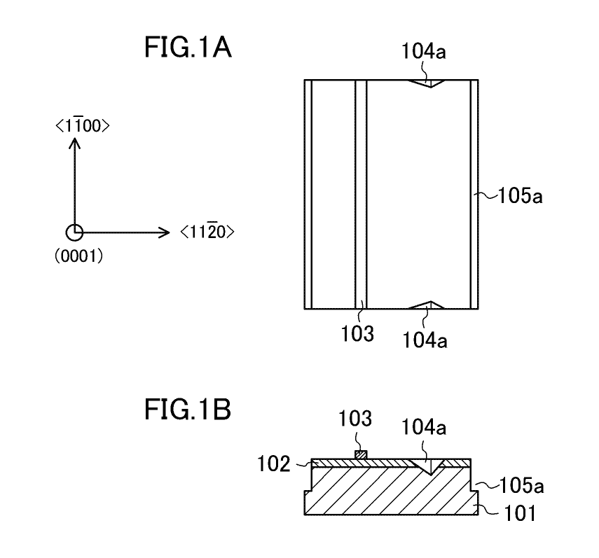

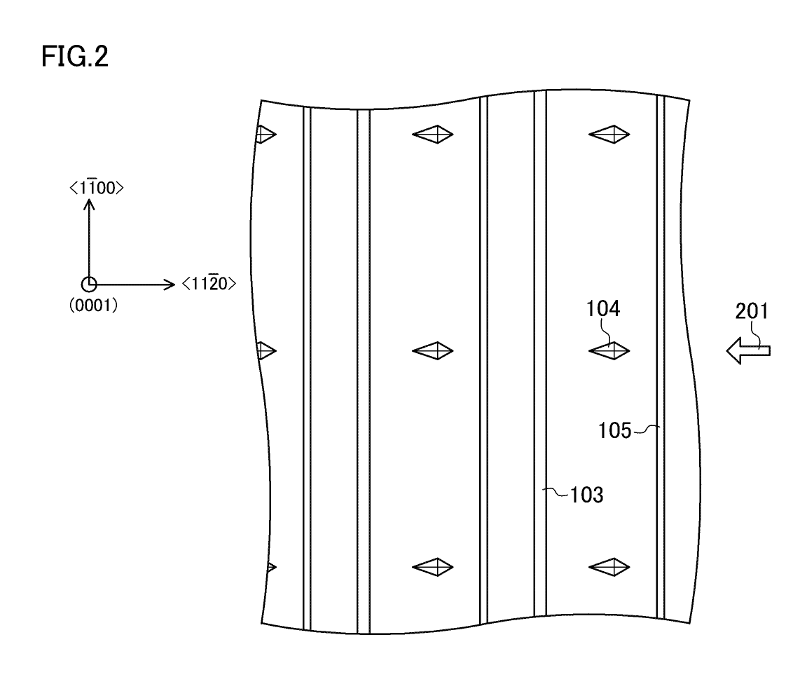

A semiconductor laser device according to an example embodiment will be described with reference to FIGS. 1A and 1B, and FIG. 2.

As shown in FIGS. 1A and 1B, for example, a lower cladding layer made of n-type aluminum gallium nitride (AlGaN) and a multiple-quantum-well active layer made of indium gallium nitride (InGaN) are formed in this order on a main surface of a semiconductor substrate 101 made of gallium nitride (GaN) whose main surface has a (0001) plane orientation by epitaxial growth. For example, an upper cladding layer made of p-type AlGaN and a contact layer made of p-type gallium nitride (GaN) are formed in this order on the multiple-quantum-well active layer, thereby forming a laminated film 102 extending from the lower cladding layer to the contact layer. Although not shown in the FIGS. 1A and 1B, a p-side electrode is formed on the laminated film 102, and an n-side electrode is formed at an opposite side of the semiconductor substrate 101 to a side thereof at which the laminated film 102 is formed.

A ridge stripe portion 103 is formed on the upper cladding layer by dry etching to extend in a <1-100> crystal axis orientation. Note that the ridge stripe portion 103 is formed to be located off a center portion of the semiconductor laser device in a <11-20> orientation, so that distances from the ridge stripe portion 103 to both side surfaces of the semiconductor laser device are different from each other.

Note that the resonator length of the semiconductor laser device in the <1-100> orientation is 800 μm, the width of the semiconductor laser device in the <11-20> orientation is 150 μm, and the width of a part extending from the ridge stripe portion 103 to one of the side surfaces of the semiconductor laser device in one direction is 100 μm.

First level-different scribed portions 104a are formed so that each of the first level-different scribed portions 104a is provided only in a part of a resonator surface, i.e., the (1-100) plane in the laminated film 102, which is located between the ridge stripe portion 103 and one of the side surfaces of the semiconductor laser device in one direction, and second level-different scribed portions 105a are formed in the side surfaces of the semiconductor laser device. Each of the first level-different scribed portions 104a is formed so as not to be in contact with the second level-different scribed portions 105a. That is, the first level-different scribed portion 104a is formed to be located between an associated one of the second level-different scribed portion 105a and the ridge stripe portion 103.

The cross-sectional shape of the first level-different scribed portion 104a taken along the resonator surface is triangular. Note that in the present specification, a line segment connecting two apexes located at a top surface of the laminated film 102 is defined to be one of the sides of the cross-sectional shape of the first level-different scribed portion 104a. An angle of an inclined part of the cross-sectional triangular shape located closer to the ridge stripe portion 103 is smaller than an angle of an inclined part of the cross-sectional triangular shape located closer to the second level-different scribed portion 105a. However, the cross-sectional shape of the first level-different scribed portion 104a is not limited to a triangular shape, but may be any polygonal shape. The polygonal shape means herein a plane shape formed by three or more line segments.

As shown in FIG. 2, the first level-different scribed portion 104a and the second level-different scribed portion 105a correspond respectively to a first scribed groove portion 104 and a second scribed groove portion 105 before dividing into chips. Note that an arrow 201 indicates a cleavage direction.

According to the example embodiment, after dividing into chips, the quality of the side surfaces and resonator surface of a divided semiconductor laser device can be improved, and thus, the yield of chips having the above-described shape can be improved.

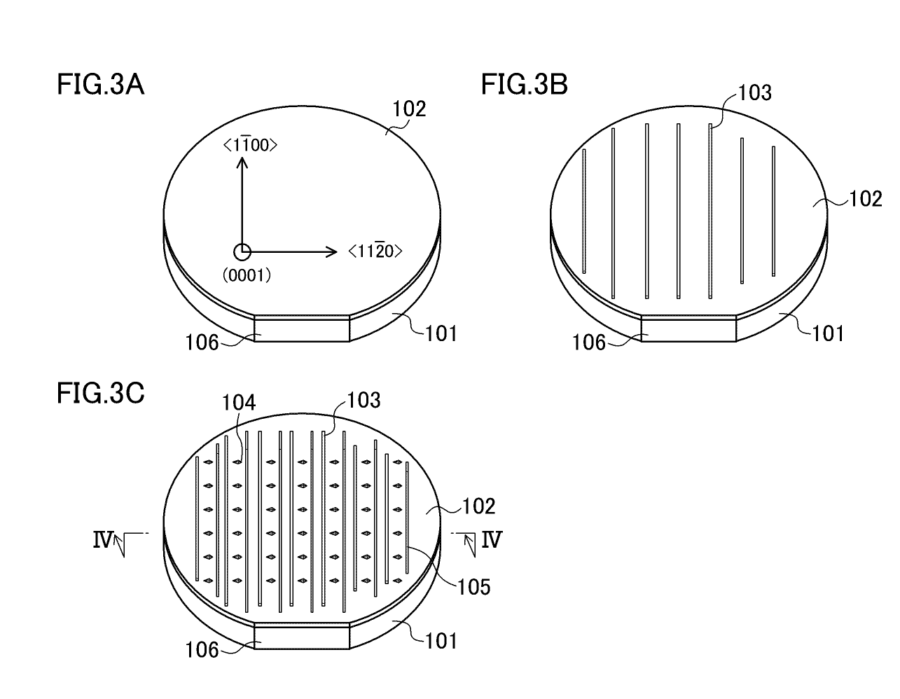

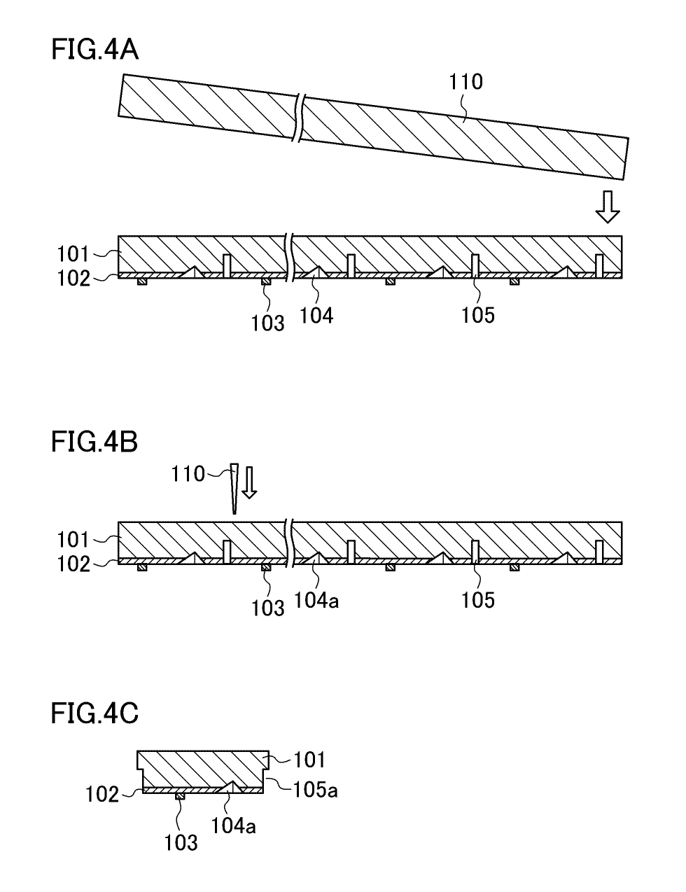

A method for fabricating the semiconductor laser device according to the example embodiment will be described hereinafter with reference to FIGS. 3A-3C and FIGS. 4A-4C.

First, as shown in FIG. 3A, a lower cladding layer made of n-type AlGaN, a multiple-quantum-well active layer made of InGaN, an upper cladding layer made of p-type AlGaN, and a contact layer made of p-type GaN, etc., are formed in this order on a main surface of a semiconductor substrate 101 made of GaN which has a (0001) plane orientation, thereby forming a laminated film 102.

Next, as shown in FIG. 3B, etching is performed using an orientation flat 106 as a reference, thereby forming, in an upper part of the laminated film 102, ridge stripe portions 103 which are to serve as optical waveguides so that the ridge stripe portions 103 extend in a <1-100> crystal axis orientation.

Next, as shown in FIG. 3C, a plurality of first scribed groove portions 104 are formed to be arranged in a <11-20> orientation and spaced from one another, and second scribed groove portions 105 are formed so that each of the second scribed groove portion 105 continuously extends in a <1-100> orientation. Although not shown in FIG. 3C, a p-side electrode is formed on the laminated film 102, and an n-side electrode is formed at an opposite side of the semiconductor substrate 101 to a side thereof at which the laminated film 102 is formed.

Next, as shown in FIG. 4A, a blade 110, etc., is pressed against a back surface of the semiconductor substrate 101 along the first scribed groove portions 104 from one end (the right side of FIG. 4A) to the other end (the left side of FIG. 4A) to cleave the semiconductor substrate 101 and the laminated film 102 so that a (1-100) plane of the laminated film 102 serves as a resonator surface, thereby dividing the wafer into a plurality of bars. Thereafter, a dielectric protective film may be provided to coat the resonator surface to block oxidation of the resonator surface and control the reflectivity of the resonator surface.

Next, as shown in FIG. 4B, the blade 110, etc., is pressed against the back surface along the second scribed groove portions 105, thereby forming a plurality of semiconductor laser devices (FIG. 4C). In this process step, the first scribed groove portions 104 and the second scribed groove portions 105 become first level-different scribed portions 104a and second level-different scribed portions 105a, respectively.

According to this embodiment, the first scribed groove portions 104 are arranged to be spaced from one another in a region between each of the second scribed groove portions 105 and an associated one of the ridge stripe portions 103. Also, as shown in FIG. 3C, the first scribed groove portions 104 are provided only at one side of the ridge stripe portion 103, but may be provided at both sides of the ridge stripe portion 103. The first scribed groove portions 104 are arranged so that a line of the first scribed groove portions 104 is formed between the ridge stripe portion 103 and the second scribed groove portion 105, but may be arranged so that a plurality of lines of the first scribed groove portions 104 may be formed between the ridge stripe portion 103 and the second scribed groove portion 105.

In dividing the wafer along the second scribed groove portion 105 into the bars, if the second scribed groove portion 105 has irregularities along the direction of dividing the wafer in a region around intersections of the second scribed groove portions 105 with the first scribed groove portions 104, stress spreads and the wafer cannot be divided along a desired direction. Thus, cracks and chips might be generated at four corners of a chip. According to this embodiment, the generation of cracks and chips at four corners of a chip, i.e., a semiconductor laser device can be greatly reduced. Also, there may be a discontinuous part in the second scribed groove portion 105, as long as the discontinuous part does not cause the generation of cracks and chips at four corners of a chip.

The scribed groove portions can be formed by etching, laser irradiation, or diamond scribing. Specifically, in laser irradiation, if the first scribed groove portions 104 directly intersect the second scribed groove portions 105, intersections of the first scribed groove portions 104 and the second scribed groove portions 105 are irradiated with laser twice, so that deep grooves are formed at four corners of a chip so as to look like dots. This causes not only the generation of cracks at the time of handling of the wafer but also the generation of irregularities along both of the cleavage line direction and the dividing line direction, so that the generation rate of cracks and chips at four corners of a chip is increased. In view of the foregoing, the method for fabricating a semiconductor laser device according to this embodiment is very advantageous, in particular, when scribed groove portions are formed by laser irradiation.

The first scribed groove portions 104 are preferably provided at the top-surface side of the laminated film 102. A reason for this is that a higher location accuracy can be achieved when an alignment is performed according to major structures such as the ridge stripe portions 103 provided on the top surface, etc., and then, scribed groove portions are formed. Furthermore, since cleavage is performed by pressing the blade 110 against an opposite surface of the semiconductor substrate 101 to the surface which has been scribed, cleavage is preferably performed by pressing the blade 110 at the back side of the GaN substrate 101 at which less structures are formed. Thus, damages on the ridge stripe portions 103 can be prevented in this case.

Similarly, the second scribed groove portions 105 are also preferably provided at the top-surface side of the laminated film 102. In general, a blue-violet laser device is fabricated using a junction-up mounting technique, and thus, the semiconductor laser device is mounted on a submount so that the back surface of the semiconductor laser device is placed on the submount with a solder material interposed therebetween. If scribed groove portions are formed at the back-surface side by laser irradiation, debris (flying particles generated in scribing) are generated near each of the scribed groove portions, and thus, the wetness of the solder material is reduced, thus resulting in reduction in shear strength (adhesiveness) between the submount and the semiconductor laser device.

For the foregoing reasons, it is preferable that the first scribed groove portions 104 and the second scribed groove portions 105 are provided together on the same surface (the top-surface side).

The cross-sectional shape of the first scribed groove portion 104 taken along the resonator surface is triangular. An angle of an inclined part of the cross-sectional triangular shape located closer to the ridge stripe portion 103 is smaller than an angle of an inclined part of the cross-sectional triangular shape located closer to the second scribed groove portion 105. In this case, the cross-sectional shape of the first scribed groove portion 104 is not limited to a triangular shape, but may be any polygonal shape.

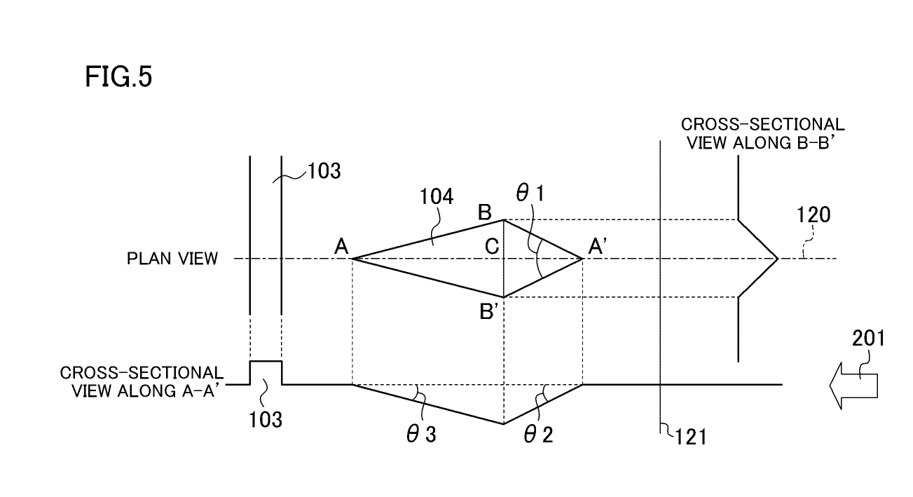

Reasons for this will be described with reference to FIG. 5. In FIG. 5, the arrow 201 indicates a cleavage direction.

As shown in FIG. 5, the plane shape of the first scribed groove portion 104 is quadrangular, and the cross-sectional shape of the first scribed groove portion 104 taken along a cleavage line 120 is triangular. Assume that opposite two apexes (A and A′) of the quadrangular shape are located on the cleavage line 120 and, as shown in the plan view of FIG. 5, an angle at the apex A′ of the first scribed groove portion 104 located closer to a chip dividing line 121 when viewed from the top is θ1. Also, assume that, as shown in the cross-sectional view of FIG. 5, an angle of an inclined part located closer to the chip dividing line 121 is θ2, and an angle of an inclined part located closer to the ridge stripe portion 103 is θ3.

Note that the shape of the first scribed groove portion 104 is not limited to the foregoing shape, but the first scribed groove portion 104 may have any shape, e.g., a pyramid shape, etc., having opposite two apexes on the cleavage line 120 and a linear valley line between the apexes.

In this embodiment, the width (B-B′) of the first scribed groove portion 104 is 3 μm in view of the range of variation in deviation from a cleavage surface to be captured. In this case, variations in resonator length are within 3 μm. The depth of the first scribed groove portion 104 is 10 μm, the length (A′-C) of a part of the first scribed groove portion 104 located in an upstream area in the cleavage direction is 15 μm, and the length (C-A) of a part of the first scribed groove portion 104 located in a downstream area in the cleavage direction is 30 μm. Thus, the total length of the first scribed groove portion 104 is 45 μm.

In FIG. 5, since the wafer is cleaved by pressing the wafer from the side of the chip dividing line 121, the cleavage direction is from the chip dividing line 121 side toward the ridge stripe portion 103 side. In this case, a triangle (A′-B-B′) in the upstream area in the cleavage direction corrects a cleavage surface deviated from the cleavage line 120 so that the cleavage surface is back along the cleavage line 120. The deviated cleavage surface is captured between the apexes A′ and B of the first scribed groove portion 104 or between the apexes A′ and B′ of the first scribed groove portion 104, cleavage proceeds via an inclination of an A′-B-C plane or an inclination of an A′-B′-C plane toward a bottom part of a pyramid shape, and then, the cleavage surface is guided to be on the cleavage line 120. Thus, advantageously, deviation of cleavage can be corrected. The angle θ1 may be an angle with which a width necessary for capturing the cleavage surface deviated from the cleavage line 120.

A triangle (A-B-B′) in the downstream area in the cleavage direction guides the cleavage surface to the cleavage line 120, and then, accurately along the valley line. The cleavage surface guided to be on the cleavage line 120, and cleavage proceeds along the cleavage line 120, so that a cleaved mirror surface can be formed to extend toward the ridge stripe portions 103. However, there are cases where the cleavage surface cannot be guided accurately enough from the triangle (A′-B-B′) to the cleavage line 120, and thus, a cleave surface with poor quality in which cracks are generated to extend toward the ridge stripe portions 103 might be obtained. However, even in such a case, in the semiconductor laser device of this embodiment, the generation of cracks near the ridge stripe portion 103 can be reduced.

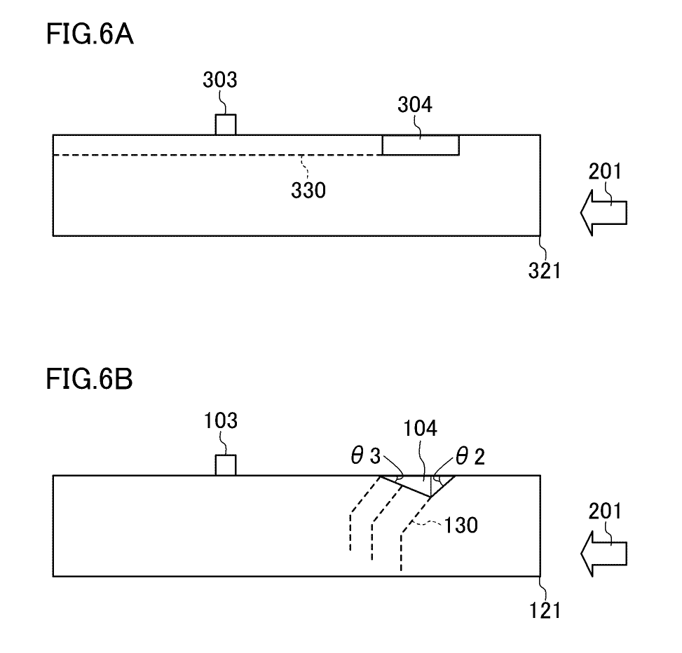

The foregoing mechanism will be described with reference to FIGS. 6A and 6B.

Conventionally, when cleavage proceeds from a chip dividing line 321 side toward a ridge stripe portion 303 side, as shown in FIG. 6A, edge cracks (minute level differences) 330 generated from a first scribed groove portion 304 propagate in the lateral direction to reach the ridge stripe portion 303. Such level differences influence optical characteristics such as a spread angle of laser light, etc. In this embodiment, as shown in FIG. 6B, edge cracks 130 are mostly generated from a bottom part and an inclined part of the triangular cross-sectional shape where stresses tend to be concentrated to extend in a direction perpendicular to the inclined part, and then, proceed toward the back surface of the substrate. As described above, when θ3 is smaller, cracks easily proceed toward the back surface of the substrate, and therefore, cracks can be substantially prevented from proceeding toward the ridge stripe portion 103. When θ3 is large, a valley line of a triangle (A-B-B′ of FIG. 5) has a small length, and thus, a deviated cleavage surface cannot be sufficiently guided to the valley line. As a result, cracks with large level differences are generated, cause the generation of other cracks one after another, and proceed toward the ridge stripe portion 103. Thus, the quality of the cleavage surface near the ridge stripe portion 103 is impaired.

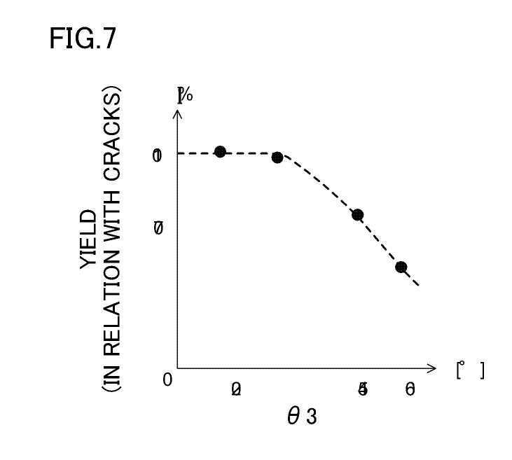

The results of a study on the relationship between θ3 of FIG. 3 and the generation rate of cracks in the resonator surface will be described with reference to FIG. 7.

As shown in FIG. 7, for example, when θ3 is larger than 20 degrees, the generation rate of cracks near the ridge stripe is increased, and the yield is gradually reduced. Thus, optical characteristics are affected.

Therefore, θ3 needs to be made small. However, since θ2 is provided for capturing, if a cleavage surface is deviated, the deviated cleavage surface from the cleavage line, θ2 does not have to be set to be small. If θ2 is small, the deviated cleavage surface cannot be guided to the bottom part of the scribed groove portion, and thus, a further deviation occurs. Therefore, θ2 may be set to be an angle so that the scribed groove portion has a length suitable for a layout in which a chip width is reduced. Thus, θ3<θ2 is preferable, and the cross-sectional shape of the first scribed groove portion taken along the direction perpendicular to the ridge stripe portion is preferably asymmetric, where the angles at the both ends of the ramp portion are different from each other.

As shown in FIG. 5, the first scribed groove portion 104 may be formed to be located at a distance of 30 μm or more from the ridge stripe portion 103. Thus, the length of the first scribed groove portion 104 is restricted to a length which is smaller than the length of a part extending from the ridge stripe portion 103 to the second scribed groove portion 105 by 30 μm or more. In contrast, in a semiconductor laser device mounted with its p-side up, wire bonding is provided to this region, and thus, reduction in the chip width is limited. To meet the above-described conditions, the length of the first scribed groove portion 104 has to be set to be as small as possible. According to the results described above, the length of the first scribed groove portion 104 can be reduced by increasing θ2 while maintaining the same edge angle θ3 for guiding cleavage to obtain an asymmetric shape.

Also, edge cracks propagate in the direction in which cleavage proceeds, and thus, cracks do not propagate toward the second scribed groove portion 105 located at an opposite part of the semiconductor laser device to a part thereof to which the cleavage proceeds. Therefore, the generation rate of cracks and chips in secondary cleavage can be further reduced.

The semiconductor laser device and the method for fabricating the semiconductor laser device according to the example embodiment can improve the quality of the side surfaces and resonance surface of a divided semiconductor laser device, thus resulting in an increased yield of chips having a desired shape.

As described above, the semiconductor laser device and the method for fabricating the semiconductor laser device according to the present disclosure can improve the quality of the side surfaces and resonance surface of a divided semiconductor laser device, thus resulting in an increased yield of chips having a desired shape. Therefore, the present disclosure is useful for a semiconductor laser device including a ridge stripe portion and a method for fabricating the semiconductor laser device.

What is claimed is:

1. A semiconductor laser device, comprising:
a semiconductor laminated film including a lower cladding layer, an active layer, and an upper cladding layer having a ridge stripe portion which are stacked in this order on a semiconductor substrate,
wherein the semiconductor laminated film includes a first scribed level-different portion formed in a resonator surface which is an edge surface of the semiconductor laminated film intersecting the ridge stripe portion and a second scribed level-different portion formed in each side surface of the semiconductor laminated film extending in parallel to the ridge stripe portion,
the first scribed level-difference portion is located between the second scribed level-different portion and the ridge stripe portion, a cross-sectional shape of the first scribe level-different portion taken along the resonator surface is polygonal, and
one of angles of inclined parts which is located closer to the ridge stripe portion is smaller than the other one of the angles located closer to the second scribed portion, the inclined parts being sides of the polygonal shape which are in contact respectively with both ends of an upper side of the polygonal shape.

2. A method for fabricating a semiconductor laser device, the method comprising the steps of:
(a) forming a semiconductor laminated film including a lower cladding layer, an active layer, and an upper cladding layer stacked in this order on a semiconductor substrate;
(b) forming ridge stripe portions in an upper part of the semiconductor laminated film;
(c) forming a plurality of first scribed groove portions in the semiconductor laminated film so that the first scribed groove portions are arranged to be spaced from one another in a direction perpendicular to the ridge stripe portions;
(d) forming second scribed groove portions in the semiconductor laminated film so that the second scribed groove portions extend in a direction parallel to the ridge stripe portions;
(e) cleaving the semiconductor substrate and the semiconductor laminated film using the first scribed groove portions so that the semiconductor substrate and the semiconductor laminated film are divided into bars; and
(f) dividing the bars obtained by cleaving the semiconductor substrate and the semiconductor laminated film into chips using the second scribed groove portions,
wherein
the first scribed groove portions are arranged to be spaced from one another in a region between each of the ridge stripe portions and an associated one of the second scribed groove portions,
a cross-sectional shape of each of the scribed groove portions taken along a direction perpendicular to the ridge stripe portions is polygonal,
one of angles of inclined parts which is located closer to an associated one of the ridge stripe portions is smaller than the other one of the angles located closer to an associated one of the second scribed portions, the inclined parts being sides of the polygonal shape which are in contact respectively with both ends of an upper side of the polygonal shape, and
in the step (e), each of the first scribed groove portions is pressed so that pressing force is applied in a direction from a part of the first scribed groove portion located closer to the associated one of the second scribed groove portions to a part of the first scribed groove portion located closer to the associated one of the ridge stripe portions, thereby cleaving the semiconductor substrate and the semiconductor laminated film.

3. The method of claim 2, wherein
the semiconductor substrate is made of nitride semiconductor whose main surface has a (0001) plane orientation, and
in the step (e), the semiconductor substrate and the semiconductor laminated film are cleaved along a (1-100) orientation plane.

4. The method of claim 2, wherein
each of the second scribed groove portions is a groove portion continuously extending in parallel to the ridge stripe portion.

5. The method of claim 2, wherein in the steps (c) and (d), at least one of the first scribed groove portions or the second scribed groove portions are formed by laser irradiation.
